(19) United States
(12) Patent Application Publication
(10) Pub. No.: US 2013/0260047 A1
(43) Pub. Date: Oct. 3, 2013

(54) COATING AND METHODS THEREOF

(71) Applicant: Rajan BAMOLA, Santa Fe Springs, CA (US)

(72) Inventor: Rajan BAMOLA, Santa Fe Springs, CA (US)

(21) Appl. No.: 13/851,046

(22) Filed: Mar. 26, 2013

Related U.S. Application Data
(60) Provisional application No. 61/616,380, filed on Mar. 27, 2012.

(51) Int. Cl. C23C 4/00; C23C 16/448

(52) U.S. Cl. CPC C23C 4/00; C23C 16/448
USPC 427/446; 427/248.1; 423/263

(57) ABSTRACT

The present invention discloses a nano-crystalline ceramic structure coat of resistive material and a method thereof for a substrate. The coating method includes the use of a resistive material solution diluted to a composition that is capable of atomization into atomized vapor particles, and conveyance of the atomized vapor particles onto a substrate, forming a conformal layer of substantially dehydrated compound. Further application of thermal energy consolidates the conformal layer into a coating of the nano-crystalline ceramic structure, with enhanced ceramic bonding with the substrate.

### CROSS-REFERENCE TO RELATED APPLICATIONS

This Application claims the benefit of priority of the co-pending U.S. Provisional Utility Patent Application No. 61/616,380, filed 27 Mar. 2012, the entire disclosure of which is expressly incorporated by reference herein. Where a definition or use of a term in an incorporated reference is inconsistent or contrary to the definition of that term provided herein, the definition of that term provided herein applies and the definition of that term in the incorporated reference does not apply.

### BACKGROUND OF THE INVENTION

1. Field of the Invention

This invention relates to coating and coating processes and, more particularly to plasma/gas resistant material as a coat and method of deposition of plasma/gas resistant material (as a coating) for plasma/gas chamber components.

2. Description of Related Art

Process chambers used in semiconductor material processing include components that are exposed to environments that have various types of gases and or plasmas. Due to the very aggressive erosive and or corrosive nature of the plasma and or gasses in such processing chambers, and the desire to minimize particle and/or metal contamination of semiconductor substrate processed (due to corrosion byproducts) in the chambers, it is desirable that plasma/gas-exposed components of such equipment are erosion and corrosion resistant to such gases and to the plasma. Yttrium Oxide Y₂O₃ (commonly known as Yttria) is one of many well known resistive material that has been used to coat the plasma/gas-exposed components of process chambers with the hope to protect such equipment against the corrosive nature of process chambers' plasma/gas environment.

Numerous publications concerning Yttria deposition by plasma spray, physical vapor deposition (PVD), chemical vapor deposition (CVD), sintering, or others exist. Deposition of Yttria using plasma spray on quartz or other process chamber components leads to subsurface cracks and a nontransparent coating, making the process of plasma spaying of Yttria ineffective on process chamber equipment, especially quartz. In particular, plasma spay of Yttria generate coating of Yttria with large grains of Yttria particles that are sprayed onto the process chamber component as coating. However, the large grain structures of the particles of Yttria coating have high energy boundaries that are preferentially etched out when the process chamber is used in semiconductor material processing (such as etching) using plasma etchants. These large etched out particles from the chamber components tend to contaminate the semiconductor being processed. The same difficulties exist with application of Yttria using sintering processes where the sintered coated Yttria particles also have high energy boundaries that are easily and preferentially etched out during plasma etching. Therefore, a need exist to form a Yttria coating that does not include or have a grain structure with high energy boundaries so to reduce the erosion rate of the process chamber component and eliminate the side-effect of particulate contaminants.

PVD is basically a well-known line of sight deposition of Yttria where a beam of Yttria vapor is directed towards an object. However, the process generates shadowing (areas where no coating of Yttria is applied) on the parts or sections of the components that are not within line of sight of the directed beam (i.e., out of reach of the Yttria vapor beam). Additionally, the PVD application for deposition of Yttria requires vacuum chambers and very tight process controls (e.g., temperature, pressure, and so on), which substantially increases the overall operational cost and complexity. For example, it is well known that PVD processes for application of Yttria require the use of high temperatures within the vacuum for proper adhesion of Yttria coating onto the process chamber component. However, this translates to a high thermal expansion/contraction difference (or mismatch) between process chamber components (0.55×10⁻⁶) and Yttria (8.1×10⁻⁶), which, in turn, results in vertical cracking in the coating of Yttria (especially when cooled), leading to corroded pathways within the components during plasma processes. Furthermore, and as importantly, PVD equipment is costly and the deposition rates fairly low, increasing the cost of the end product.

Other processes such as Chemical Vapor Deposition (CVD) for application of a coating of Yttria onto a process chamber component exist, but require very costly precursors (or compounds used to generate the Yttria), and further require the use of extremely high temperatures for proper application of Yttria coating, which result in the same thermal expansion/contraction mismatch as described above in relation to PVD processes.

As described above, known coating processes inherently create defects within the coat of Yttria, including generation of inherent coating structures (e.g., high energy boundaries, thermal mismatch resulting in structural cracks, etc.) that are more prone to erosion. Accordingly, coating of Yttria by known processes create an inherently faulty coating that does not provide the appropriate level of protection for process chamber components needed for resistance against the plasma/gas-exposure within the process chambers.

Therefore, in light of the above, a need exists for a coat and for a low cost and efficient process of coating that obviates any inherently created coating defects of process chamber components, and would further provide a high erosion resistance, and have high transparency (especially for quartz components).

### BRIEF SUMMARY OF THE INVENTION

A non-limiting, exemplary aspect of an embodiment of the present invention provides a method for coating a substrate, comprising:
providing a solvent;
dissolving desired solute within the solvent to form a solution;
diluting the solution to a composition capable of atomization;
cleaning the substrate;
heating the substrate;
atomizing the diluted solution into atomized vapor particles;
directing atomized vapor particles of the diluted solution towards the heated substrate to form a conformal layer of substantially dehydrated compound thereon; and
consolidating the substantially dehydrated compound into a coating of a nano-crystalline ceramic structure, with enhanced ceramic bonding with the substrate.

Another non-limiting, exemplary aspect of an embodiment of the present invention provides a method for coating a substrate, comprising:
providing a combustible solvent;
dissolving desired solute within the solvent to form a solution;
diluting the solution to a composition capable of atomization;
atomizing the diluted solution into atomized vapor particles;
igniting the atomized vapor particles of the diluted solution to substantially to ignite and remove solvent, providing additional dehydration;
directing resulting atomized vapor particle solution with substantially removed solvent towards cleaned substrate to form a conformal layer of substantially dehydrated compound on the substrate;
consolidating the substantially dehydrated compound into a coating of a nano-crystalline ceramic structure, with enhanced ceramic bonding with the substrate.

Another non-limiting, exemplary aspect of an embodiment of the present invention provides a coating, comprising an nano-crystalline structure comprised of resistive material.

Another non-limiting, exemplary aspect of an embodiment of the present invention provides a nano-crystalline structure, comprising an oxide compound with ceramic bonding structure.

Such stated advantages of the invention are only examples and should not be construed as limiting the present invention. These and other features, aspects, and advantages of the invention will be apparent to those skilled in the art from the following detailed description of preferred non-limiting exemplary embodiments, taken together with the drawings and the claims that follow.

### BRIEF DESCRIPTION OF THE DRAWINGS

It is to be understood that the drawings are to be used for the purposes of exemplary illustration only and not as a definition of the limits of the invention. Throughout the disclosure, the word “exemplary” may be used to mean “serving as an example, instance, or illustration,” but the absence of the term “exemplary” does not denote a limiting embodiment. Any embodiment described as “exemplary” is not necessarily to be construed as preferred or advantageous over other embodiments. In the drawings, like reference character(s) present corresponding part(s) throughout.

Referring to the drawings in which like reference character(s) present corresponding part(s) throughout:

FIG. 1 is a non-limiting, exemplary illustration of a coating process of a substrate in accordance with an embodiment of the present invention;

FIG. 2A is a non-limiting, exemplary flowchart illustration of an embodiment of a coating process of the substrate illustrated in FIG. 1 using non-combustible solvent in accordance with the present invention;

FIG. 2B is a non-limiting, exemplary flowchart illustration of another embodiment of a coating process of the substrate illustrated in FIG. 1 using combustible solvent in accordance with the present invention;

FIG. 3A is a non-limiting, exemplary illustration of a surface structure of Yttria on a quartz (includes loose particulates) in accordance with an embodiment of the present invention, and FIG. 3B is a non-limiting, exemplary illustration of a magnified surface structure of Yttria on the quartz shown in FIG. 3A;

FIG. 4A is a non-limiting, exemplary illustration of a cross-sectional structure of Yttria coat on a quartz in accordance with an embodiment of the present invention, and FIG. 4B is a non-limiting, exemplary illustration of a magnified cross-sectional structure of Yttria coat on the quartz shown in FIG. 4A;

FIG. 5A is a non-limiting, exemplary illustration of an actual test conditions and results for a component (e.g., a quartz) coated in accordance with an embodiment of the present invention;

FIGS. 5B and 5C are non-limiting, exemplary illustration of the tested coated component of FIG. 5A shown under Scanned Electron Microscope with FIG. 5C a further magnified illustration of FIG. 5B; and

FIGS. 5D and 5E are non-limiting, exemplary illustration of the tested uncoated component of FIG. 5A shown under Scanned Electron Microscope with FIG. 5E a further magnified illustration of FIG. 5D.

### DETAILED DESCRIPTION OF THE INVENTION

The detailed description set forth below in connection with the appended drawings is intended as a description of presently preferred embodiments of the invention and is not intended to represent the only forms in which the present invention may be constructed and or utilized.

Throughout the disclosure, any specific reference to Yttrium Oxide Y₂O₃ (i.e., Yttria) is meant as illustrative and for convenience of example of a resistive material, and for discussion purposes only. That is, the disclosed coating and coating methods should not be limited to the use of Yttria as a resistive material against the corrosive/erosive nature of process chambers' plasma/gas environment. The various embodiments of the present invention may use other well known resistive materials, non-limiting, non-exhaustive exemplary listings of which may include a family of plasma/gas erosion/corrosion resistant oxides. Non-limiting examples of such resistive oxides may include oxides of rare earth elements, rare earth compounds, or combinations thereof, which may include both Lanthanide and Actinide series of elements, compounds, or combinations thereof. Non-limiting examples of other oxides may include yttria, zirconia, yttria-alumina-garnet (YAG), zirconia toughened alumina (ZTA), or other ternary oxides, non-limiting examples of which may include Zirconia-Yttria-Alumina (ZYA) or any combinations of any of the elements and compounds that is and may be used as “resistive material” against the corrosive/erosive nature of process chambers' plasma/gas environment.

It should be further noted that for the purposes of the various embodiments of the present invention the Yttrium Nitrate hexahydrate Y(NO₃)₃.6H₂O and Yttrium Nitrate Y(NO₃)₃ are used interchangeably.

The present invention provides a coat and low cost and efficient processes of coating that does not have any inherently created coating defects due to the coating methods. The present invention further provides a coating that is high erosion/corrosion resistance, preventing degradation of the substrate into particulate contaminants. An embodiment of the present invention provides a coating that maintains a high transparency (especially for quartz components). As described in detail below, the present invention also provide a coat with high adherence and minimal or no high-energy boundaries, which is also conformal, is very dense, and has a smooth surface. Significant advantages of the coat and the coating methods disclosed in the present invention are the ability to conduct the actual coating process in air (no vacuum is required), the use of relatively simple equipment with process control limited to very few variables, and the ability of non-line of sight processes for conformal coating of a substrate.

In general, the present invention provides nano-crystalline ceramic structure coat that may optionally be transparent, and methods thereof for a substrate. The coating methods include the use of a solution of resistive material diluted to a composition that is capable of atomization into atomized vapor particles, and conveyance of the atomized vapor particles onto a cleaned substrate (which may be optionally pre-heated first, as detailed below). The atomized vapor particles are aided in transport towards the substrate by a flow of air or nozzle onto the surface of the substrate, forming a conformal layer of substantially dehydrated compound. Further application of thermal energy consolidates the conformal layer of the substantially dehydrated compound into coating of the nano-crystalline ceramic structure (which may optionally be transparent), with enhanced ceramic bonding with the substrate. Optionally, the coated substrate may further be later cleaned to remove any residual loose particulates.

In one embodiment, the present invention discloses methods for depositing resistive material on ceramic surfaces for resisting plasma etch in semiconductor applications. The processes are applicable to glass, quartz, alumina and other elements. In particular, an embodiment of the present invention may use an ultrasonic nebulizer or ultrasonic nozzle to generate vapor from resistive material solution. In one embodiment, the vapor from resistive material may be passed over a heated substrate (for example quartz) to create a coating. In another embodiment, there is no requirement to heat substrate, but the vapor from resistive material (with a combustible solvent) is ignited (to ignite and remove solvent) prior to passing over the substrate to create the coating. The coated piece is then placed in a furnace to drive off the residual solvent (e.g., water, ethanol, etc.) and enhance the bonding in the coating. When using the ultrasonic nozzle, x-y scanning can be used to completely cover the substrate. When using the nebulizer, an air or oxygen stream can be used to carry the vapor. A few variables in the methodologies are desired solution chemistry (dilution), ultrasonic power (sufficient to create vapor particles), scanning speeds and overlaps, carrier gas flow rate, and substrate temperature during coating and post coating treatment. In a non-limiting, exemplary embodiment, transparency may be obtained at a thickness of 2-5 microns of coating. Thicker coatings (without regard to need for transparency) can be useful to protect parts that do not require transparency.

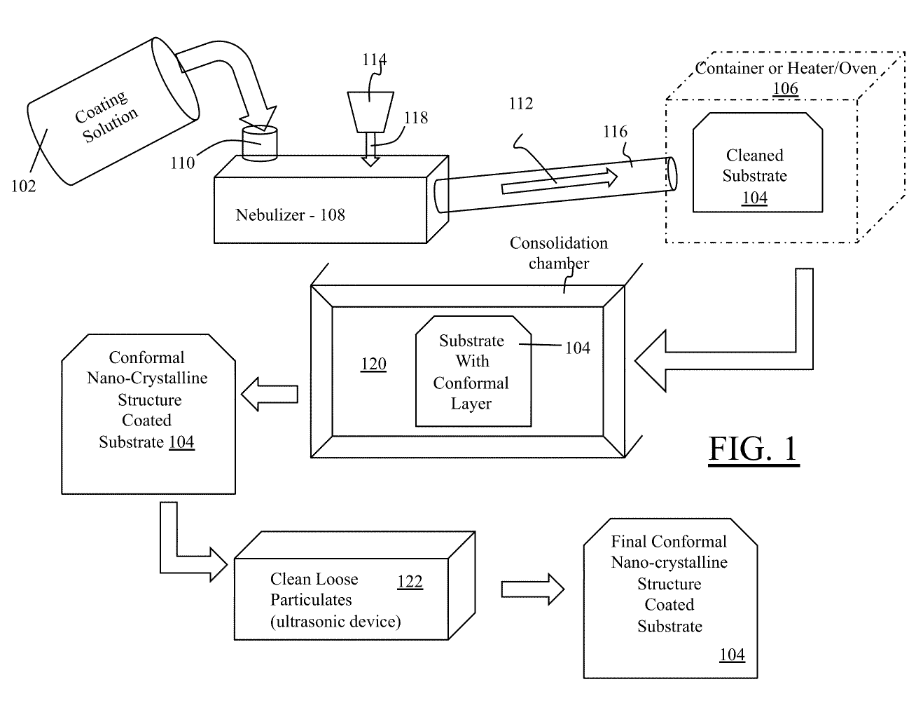

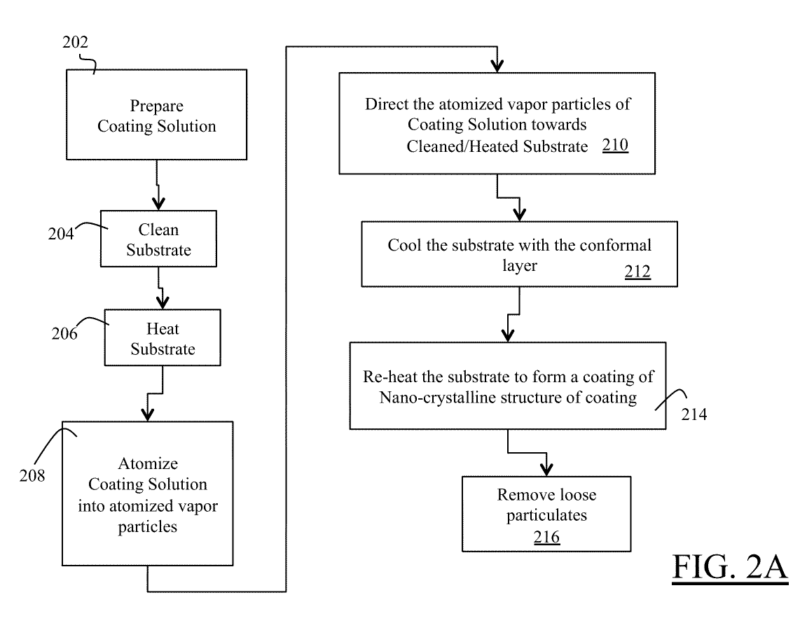

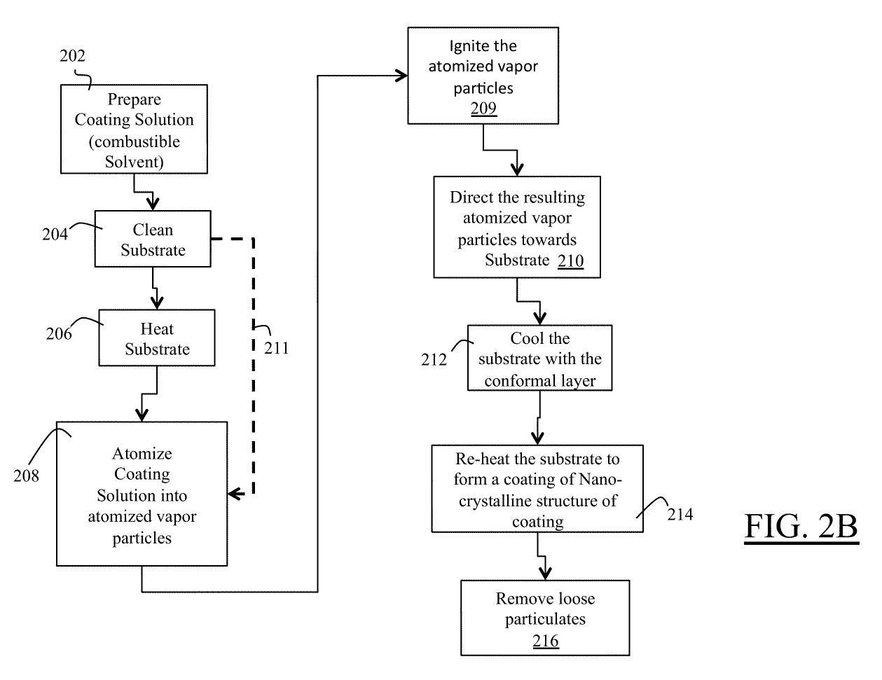

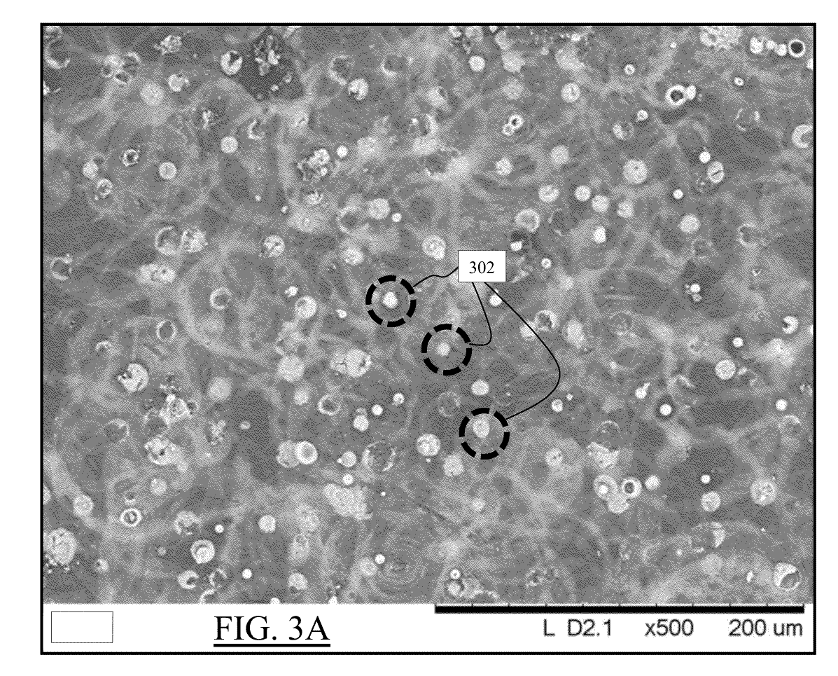

FIG. 1 is a non-limiting, exemplary schematic illustration of a coating process of a substrate in accordance with the present invention. FIG. 2A is a non-limiting, exemplary flowchart illustration of an embodiment of a coating process of the substrate illustrated in FIG. 1 using non-combustible solvent in accordance with the present invention. FIG. 2B is a non-limiting, exemplary flowchart illustration of another embodiment of a coating process of the substrate illustrated in FIG. 1 using combustible solvent in accordance with the present invention.

As illustrated in both FIGS. 1 to 2B, the present invention provides methods for coating a substrate 104, comprising the operation 202 (FIGS. 2A and 2B) of preparing of a solution 102 (FIG. 1) for processing into a final coating material. The solution (or coating solution) 102 is comprised of a solute portion that includes and comprises the desired resistive material that is diluted in a solvent to form the coating solution 102. For example, and without limitations, in one very specific, a non-limiting, exemplary embodiment, the diluted solution may comprise of a desired resistive material such as Yttrium Nitrate hexahydrate Y(NO₃)₃.6H₂O dissolved in water.

In general, most any type of solvents may be used to dissolve and dilute the solute of desired resistive material into a solution 102, so long as the solvent used vaporizes substantially as the solute. Non-limiting examples of solvents that may be used to dissolve and dilute a solute of resistive material to form the desired solution may include combustible solvents (e.g., ethanol, xylene, etc.), non-combustive solvents (e.g., water), or any other solvents that do not readily vaporize (or at least vaporize substantially as the solute of the resistive material and are suitable for particle generation via an atomization device. The obvious reason for requiring a solvent that does not readily vaporize faster than the solute is because most (if not all) of the solvent will quickly vaporize, and the remaining solute will be left behind during atomization for creation of atomized vapor particles (detailed below).

In the non-limiting, exemplary instance illustrated in FIG. 2A, an embodiment of the present invention used Yttrium Nitrate hexahydrate Y(NO)₃)₃.6H₂O dissolved in water. In general the solution 102 of Yttrium Nitrate Y(NO₃)₃.6H₂O is further diluted to a composition capable of atomization, which in this one non-limiting, exemplary embodiment is found to be about 0.001 to 1.5 molar solution of Y(NO₃)₃.6H₂O, preferably in one embodiment, the diluted solution 102 is about 0.05 molar solution of Y(NO₃)₃.6H₂O.

As further illustrated in FIG. 2A, as part of the coating process, the operation 204 requires that the targeted substrate 104 be cleaned, which may be accomplished by a vast variety of methods, a non-limiting example of which may include cleaning the substrate 104 ultrasonically, using well known ultrasonic cleaners. In general, ultrasonic cleaning is preferred because it is a non-chemical method of cleaning.

As a further part of the coating process, the operation 206 requires the application of thermal energy to heat the cleaned substrate 104. This may also be accomplished by a vast variety of methods such as the use of an illustrated heater/oven 106 to heat up the cleaned substrate 104. In general, the cleaned substrate 104 may be heated within the heater 106 to a temperature range about 200° C. to 400° C., and in one non-limiting, exemplary embodiment, preferably, to about 300° C. prior to application of any atomized vapor particles, which aids and facilitates in further dehydration of the solvent.

As part of the coating process, at operation 208, the diluted solution may be atomized into atomized vapor particles by a variety of different equipment such as a nebulizer or ultrasonic agitator or others device 108. Ultrasonic devices or agitator or nebulizers 108 are very well known and are extensively used to create an agitation of a solution to such a point where the solution is nebulized or atomized, creating atomized vapor particles. Most devices 108 include an ingress cylinder 110, which allows users to pour the desired solution to be atomized into the device 108. In the case of one, non-limiting, exemplary embodiment of the present invention, the diluted solution 102 of about 0.05 molar solution of Y(NO₃)₃6H₂O is poured into the device 108 via the ingress cylinder 110.

As a further part of the coating process, at operation 210, atomized vapor particles of diluted resistive material (e.g., Yttrium Nitrate solution Y(NO₃)₃.6H₂O) 112 are directed towards cleaned, heated substrate 104 to form a conformal layer of substantially dehydrated compound thereon. As illustrated, in this non-limiting exemplary instance, the atomized vapor particles 112 are directed toward substrate 104 within the heater 106 via using a flow of air 118 that is pumped into the device (e.g., nebulizer) 108 by an air pump 114, and the atomized vapor particles 112 are pushed within a connecting mechanism (e.g., tube) 116 into the heater 106 chamber, and onto the surface of the substrate 104 to form the conform layer of the substantially dehydrated compound thereon. It should be noted that the conformal layer thickness is a mere function of time.

As a further part of the coating process, at operation 212, the substrate 104 with the conformal layer of the substantially dehydrated compound thereon is cooled. At operation 214, further thermal energy is applied to the substrate 104, which consolidates the substantially dehydrated compound layer into a coating of nano-crystalline ceramic structure, with enhanced ceramic bonding with the substrate 104. As illustrated in FIG. 1, the pure coating of resistive material (e.g., Yttria) with the nano-crystalline ceramic structure with enhanced bonding with the substrate 104 is formed by application of thermal energy in the form of heating the substrate 104 about 400° C. to 1000° C. (in one non-limiting, exemplary preferred embodiment), the substrate 104 is heated to about 450° C. to 600° C.) within a consolidation chamber, such as an oven 120. In a non-limiting, exemplary preferred embodiment, the substrate 104 may be heated to about 450° C. to 550° C. for about 3 to 5 hours. The lower the temperature, the more time is required to “dry” the substrate 104, and the higher the temperature, the less time is required to “dry” the substrate 104.

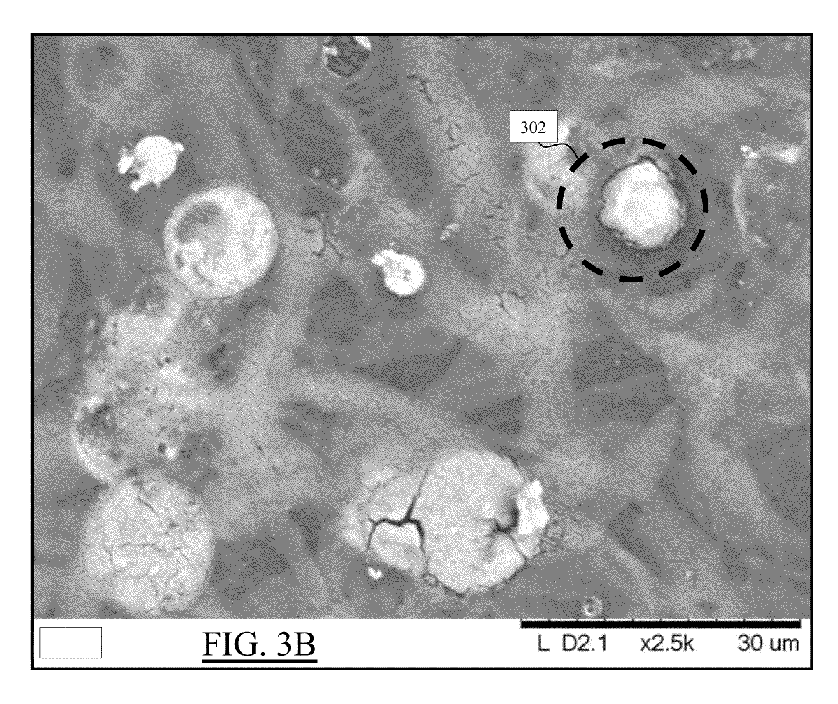

The operation 214 provides a simple, low temperature heat treat of the substrate 104 with the substantially dehydrated compound layer, removing all hydration, resulting in coating of the nano-crystal structure of desired resistive material (e.g., Yttria (Y₂O₃)) of substrate 104. This heating also consolidates the oxygen (of an Oxide component such as SiO₂ quartz) to resistive material (e.g., Yttrium) bonding by removal of all other compounds as a result of the application of thermal energy. As an optional part of the coating process, at operation 216, the coated substrate 104 is cleaned of loose particulates 302 (FIGS. 3A and 3B) using an exemplary ultrasonic device 122 to form the final conformal nano-crystalline structure resistive material.

FIG. 2B is a non-limiting, exemplary flowchart illustration of another embodiment of a coating process of the substrate illustrated in FIG. 1, using a combustible solvent in accordance with the present invention. The coating processes illustrated in FIG. 2B includes similar corresponding or equivalent processes as the coating processes that are shown in the flowchart illustrated in FIGS. 2A, and described above. Therefore, for the sake of brevity, clarity, convenience, and to avoid duplication, the general description of FIG. 2B will not repeat every corresponding or equivalent processes, operations, or functions that have already been described above in relation to the coating processes shown in the flowchart illustrated in FIG. 2A.

As illustrated in FIG. 2B, an embodiment of the present invention provides methods for coating a substrate 104, comprising the operation 202 of preparing of a solution 102 (FIG. 1) for processing into a final coating material. The solution (or coating solution) 102 in this non-limiting, exemplary embodiment shown in FIG. 2B is comprised of a solute portion that includes and comprises the desired resistive material that is diluted in a combustible solvent to form the coating solution 102. For example, and without limitations, in one very specific, non-limiting, exemplary embodiment, the diluted solution may comprise of a desired resistive material such as Y(NO₃)₃.6H₂O solute dissolved in a combustible solvent such as ethanol (C₂H₆O).

More specifically, in the non-limiting, exemplary instance illustrated in FIG. 2B, an embodiment of the present invention used Y(NO₃)₃.6H₂O as an example of a solute and dissolved and diluted the solute with ethanol (C₂H₆O) to a composition capable of atomization, which in this one non-limiting, exemplary embodiment is found to be about 0.01 molar solution.

As further illustrated in FIG. 2B, as a further part of the coating process, the operation 206 (which requires the application of thermal energy to heat the cleaned substrate 104) may optionally be bypassed (referenced as arrow 211) and not performed. In other words, the cleaned substrate 104 (as a result of the operation 204) need not be heated prior to application of any atomized vapor particles at the operational functional act 208 if a combustible solvent is used to prepare the desired resistive material solution 102 at operation 202. The operation of the heating of the substrate may optionally be bypassed due to the added operation 209 (detailed below).

As part of the coating process, at operation 208, the diluted solution may be atomized into atomized vapor particles as described above in relation to FIG. 2A. As illustrated in FIG. 2B, at the operation 209, the atomized vapor particles of the diluted resistive material solution are actually ignited to substantially “burn off” and remove the combustible solvent within atomized vapor particles of the resistive solution, providing additional dehydration thereof and thereby, enabling optionally bypassing of operation 206 of heating of the substrate. That is, as the atomized vapor particles of the diluted resistive material solution egress the atomizer device, the vapor is literally ignited or “burned” by a flame, which substantially drives off the solvent. Thus, the requirement of additional dehydration using the operation 206 is not necessarily needed if a combustible solvent is used and operation 209 is performed. The operation 209 is very similar to the well known combustion CVD process.

The advantages of using a combustible solvent enabling the processing operation 209 is that it allows for application of thicker layer of coating of resistive material onto the substrate to thereby increase the life of the substrate coated. A further advantage is that duration of dehydration in heating chamber 106 (if any) is reduced as the vapor particles are substantially dehydrated as a result of the operation 209. The less time is spent in dehydrating and consolidating the substrate the better because the substrate is not exposed to such high temperatures for long durations, which may degrade the structural integrity of the substrate. The remaining operations 210, 212, 214, and 216 are the same as those described in relation to FIG. 2A.

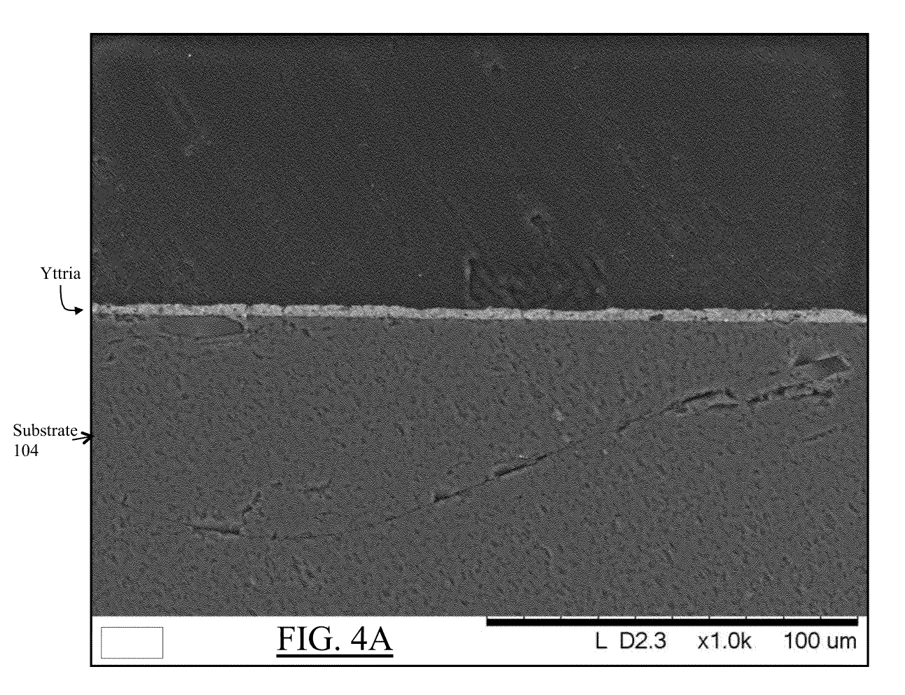

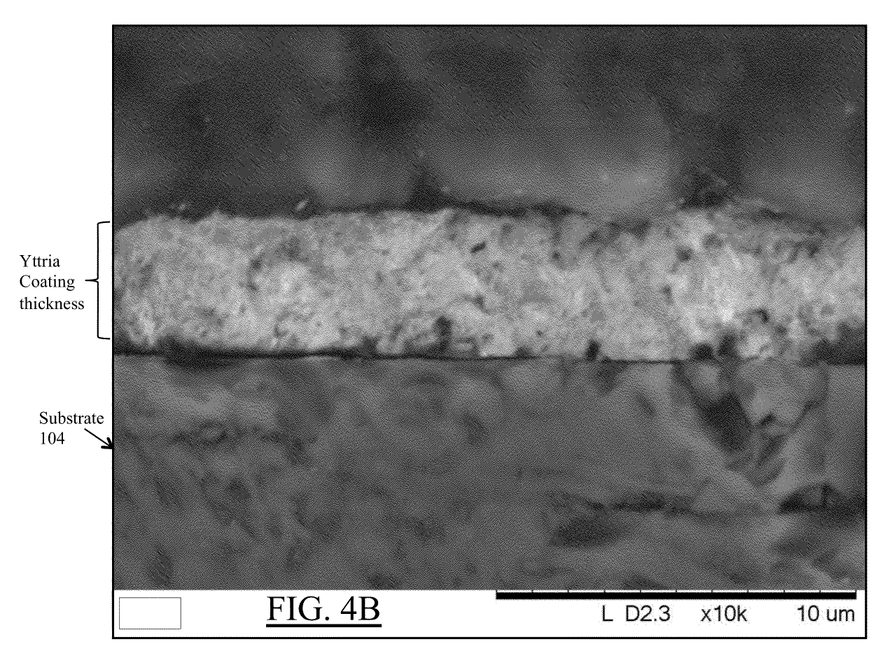

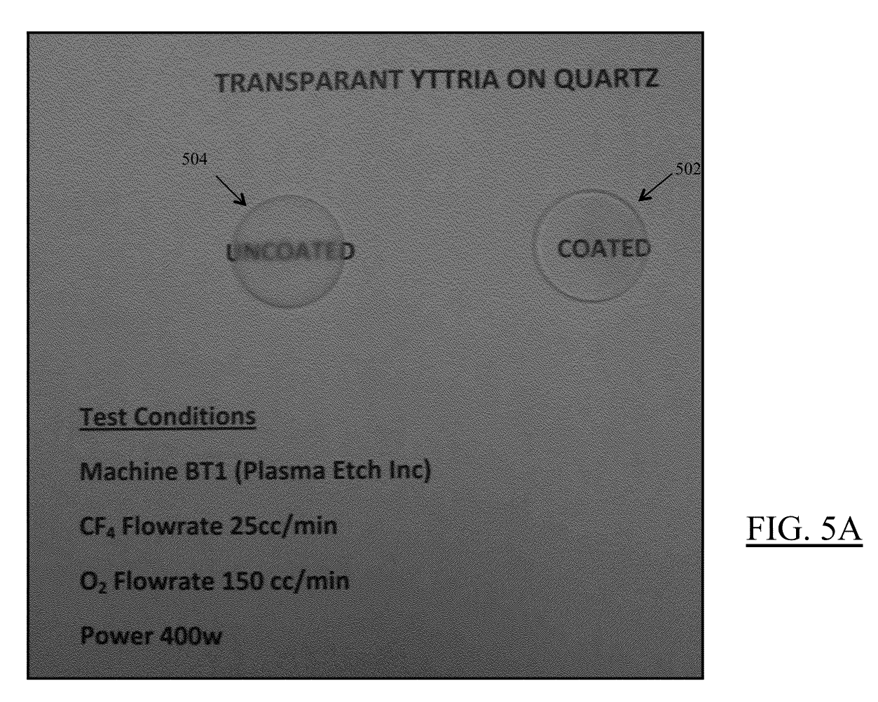

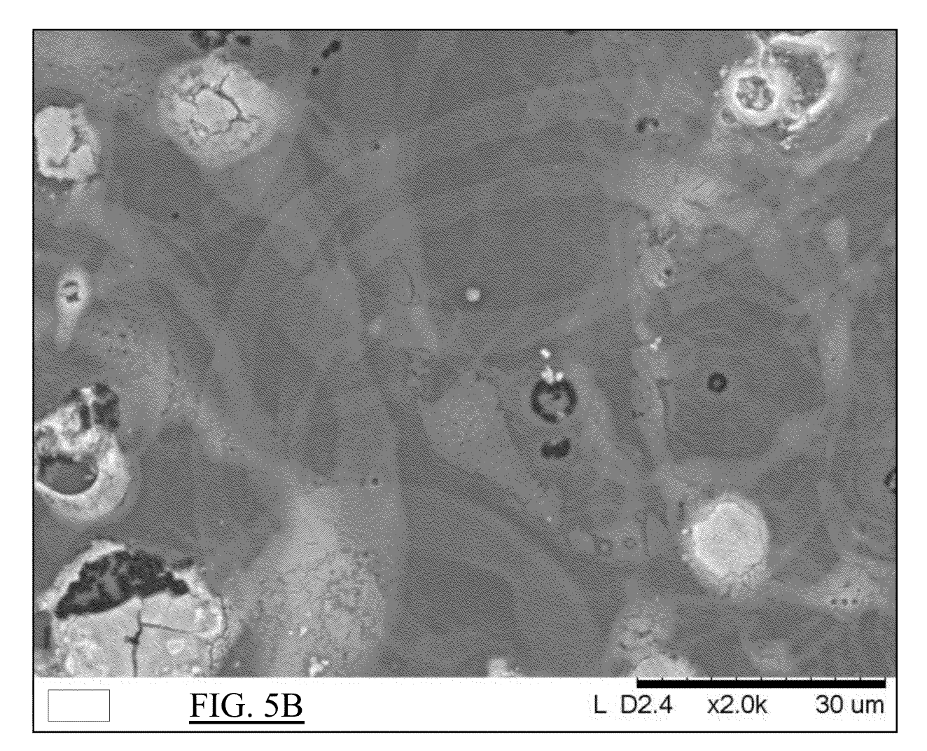

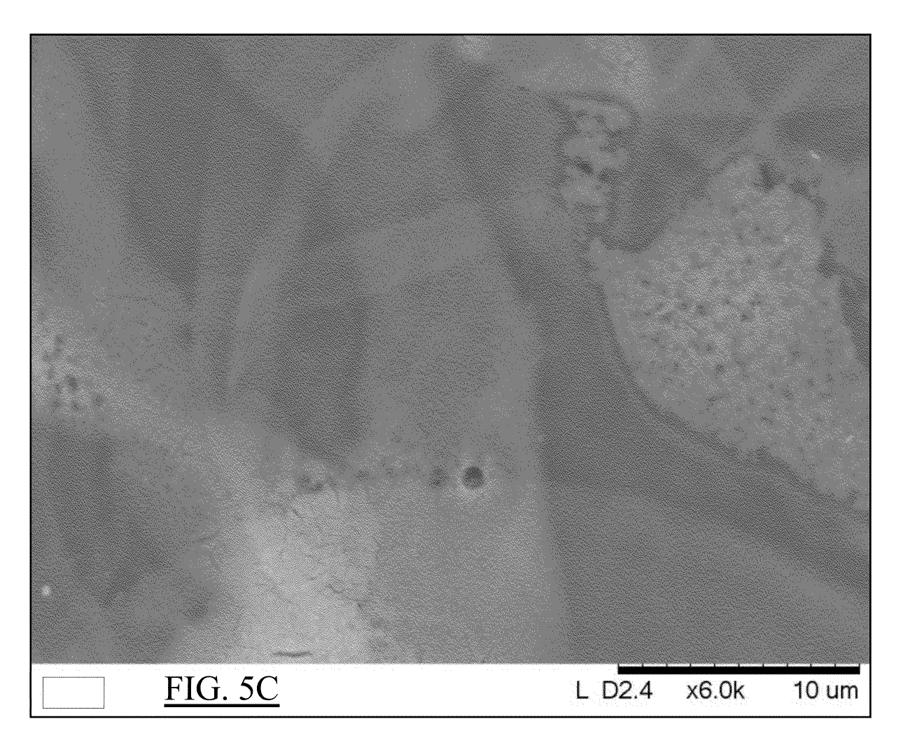

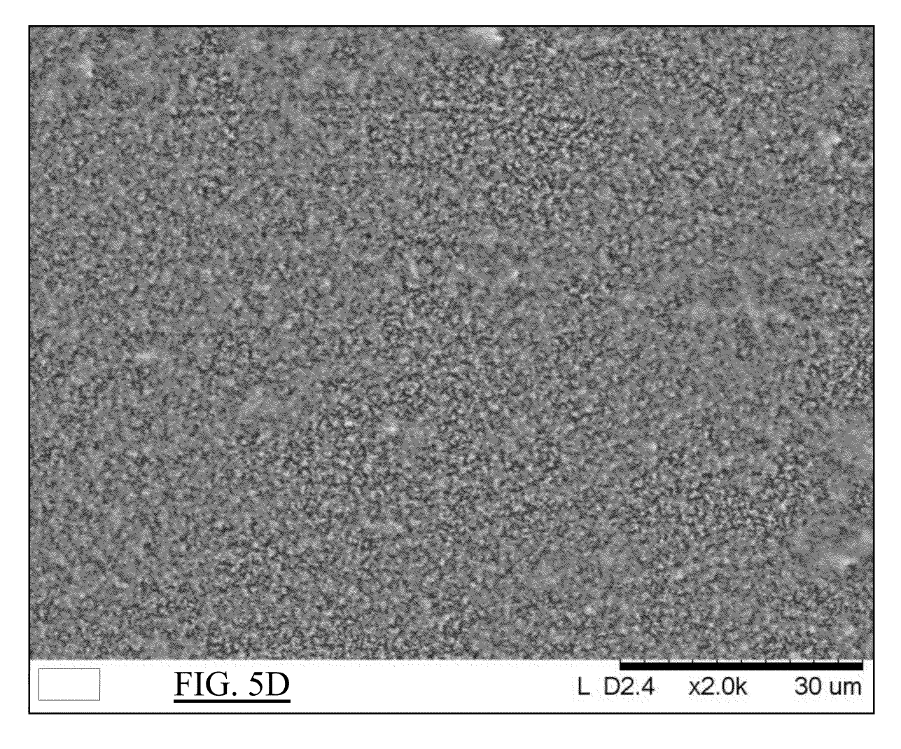

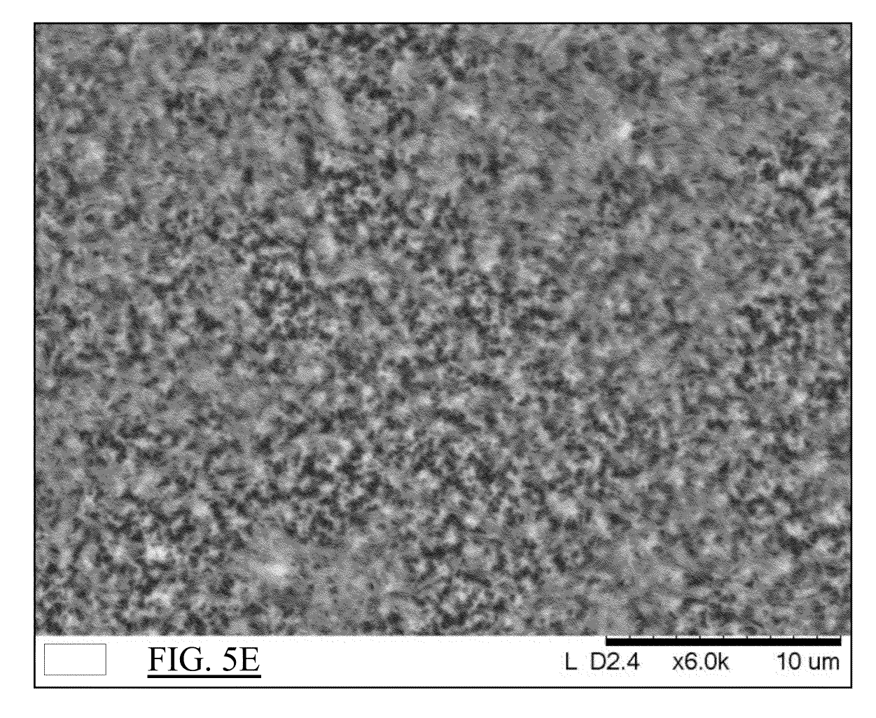

As an optional part of the coating process, at operation 216 (FIGS. 2A and 2B), the coated substrate 104 is cleaned of loose particulates 302 (FIGS. 3A and 3B) using an ultrasonic device 122 to form the final conformal nano-crystalline structure resistive material (e.g., Yttria) coated substrate 104, shown in FIGS. 4A, 4B, and 5B, 5C. During deposition of atomized vapor particles, due to surface tension, some particles do not “spread out” to form a nano-crystal structure and remain as a lump of “droplet” or loose particulates 302 on the surface of the substrate 104. Hence, ultrasonic device 122 can agitate the coated substrate 104 and “knock-off” the loose particulates 302. In general, the particulates 302 are super-saturated resistive material (e.g., oxides such as Y₂O₃) with not enough or sufficient solvent (e.g., water) in the particle droplet to allow it to overcome its own surface tension and spread, but are easily removed by ultrasonic agitation, with the cleaned substrate 104 shown in FIGS. 4A, 4B, and 5B, 5C.

FIG. 4A is a non-limiting, exemplary illustration of a cross-sectional structure of Yttria coat on quartz in accordance with the present invention, and FIG. 4B is a non-limiting, exemplary illustration of a magnified cross-sectional structure of Yttria coat on the quartz shown in FIG. 4A. As illustrated in FIGS. 4A and 4B, after the operation 216, the cross-section of the Yttria coating shows a smooth surface without any “lumps.”

FIG. 5A is a non-limiting, exemplary illustration of an actual test conditions and results for a component (e.g., a quartz) coated in accordance with a non-limiting, exemplary embodiment of the present invention. As illustrated in FIG. 5A, the coating was tested in CF₄/O₂ Plasma etch chamber (BT1 manufactured by Plasma Etch, Inc.) at 400 w for 3 hours. The CF₄ flow-rate was 25 cc/min and O₂ was 150 cc/min. The coated part 502 showed no deterioration while the uncoated part 504 was substantially etched. FIGS. 5B and 5C are non-limiting, exemplary illustration of the tested coated component 502 under Scanned Electron Microscope (SEM) with FIG. 5C a further magnified illustration of FIG. 5B. As illustrated, under SEM with large magnifications, coated component 502 does not show any deterioration or corrosion due to etching. FIGS. 5D and 5E are non-limiting, exemplary illustration of the tested uncoated component 504 under SEM with FIG. 5E a further magnified illustration of FIG. 5D. As illustrated in FIGS. 5D and 5E, the uncoated component 504 shows a substantial deterioration or corrosion under the test conditions, making component 504 non-transparent.

Referring back to FIGS. 5B and 5C, as further illustrate, the nano-crystalline structure of the resistive material (e.g., Yttria in this non-limiting exemplary embodiment) coating achieved by the coating process in accordance with the present invention. The nano-crystalline structure of the resistive material is achieved because the finally coated resistive material is initially precipitated (atomized) from a diluted solution of the resistive material within solvent with particle size so small that when dehydrated (via heating), a resistive material coating with nano-crystalline structure is formed on the substrate. The resistive material coating with nano-crystalline structure has no boundaries and hence, no etchant can penetrate the coating to deteriorate (corrode) the coated surface of the component. It should be noted that the formation of the resistive material coating from the water-diluted solution (e.g., Yttrium Nitrate) when heated is a result of sol-gel processing. It should be noted that merely dipping a substrate within the water diluted solution of resistive material (e.g., Yttrium Nitrate) and dehydrating it will result in cracks (also known as “mud” cracks) on the coating due to solvent (e.g., water) run-off and hence, the sol-gel processing by itself does not result in an nano-crystalline structures. Therefore, conventional coating processes (PVD, CVD, plasma spay, etc.) use resistive material such as Yttria to generate Yttria coating that inherently includes discrete Yttria particles with grain boundaries highly susceptible to etching. The present invention does not use resistive material such as Yttria, but a diluted solution of resistive material such as Yttrium Nitrate that is atomized and deposited as a conformal layer onto a substrate, which through sol-gel processes, the conformal layer of Yttrium Nitrate plus water results into Yttria coating with nano-crystalline structure. As indicated above, the solvent used to dilute the resistive material (e.g., Yttrium Nitrate) must be of type that does not readily vaporize, non-limiting non-exhaustive listings of which may include water or ethanol suitable for particle generation via an atomization device such as an ultrasonic agitator.

It should further be noted that the coating methods of the present invention generate a coating that forms both mechanical and chemical bonding within the resistive material (e.g., Yttria) particulates and further, between the resistive material (e.g., Yttria) and the substrate. Quartz is a non-limiting example of a process chamber component or substrate, which is comprised of SiO₂ with Si—O bonds. As a result of the processes of a non-limiting, exemplary embodiment of the present invention, the Si—O bond of the SiO₂ chemically reacts with the conformal layer of atomized Y(NO₃)₃.6H₂O (via a sol-gel processing) to form Y—O and Si—O chemical bonds on the surface of the quartz, resulting in Yttria coating with a nano-crystalline structure. The same is true for other substrates such as pure Si or those comprised of Al₂O₃ with Al—O bonds. As a result of the processes of a non-limiting, exemplary embodiment of the present invention, the Al—O bond of the Al₂O₃ chemically reacts with the conformal layer of atomized Y(NO₃)₃.6H₂O (via a sol-gel processing) to form Y—O and Al—O chemical bonds on the surface of the Al₂O₃ substrate, resulting in Yttria coating with nano-crystalline structure.

Accordingly, the coating processes disclosed provides coatings that perform exceptionally well, outperforming most conventional CVD type coatings. X-ray diffraction has revealed that phases other than yttrium oxide (Y₂O₃) exist in these coatings depending on the extent of curing achieved. Therefore the good performance of this coating may not be attributed to the existence of Y₂O₃ alone, but may also be attributed to various phases thereof.

Although the invention has been described in considerable detail in language specific to structural features and or method acts, it is to be understood that the invention defined in the appended claims is not necessarily limited to the specific features or acts described. Rather, the specific features and acts are disclosed as exemplary preferred forms of implementing the claimed invention. Stated otherwise, it is to be understood that the phraseology and terminology employed herein, as well as the abstract, are for the purpose of description and should not be regarded as limiting. Therefore, while exemplary illustrative embodiments of the invention have been described, numerous variations and alternative embodiments will occur to those skilled in the art. For example, another variation of the process involves electrically charging the atomized particles for example by means of a Van de Graaf generator, or the well known electrostatic guns used for polymeric coatings, and biasing the substrate to allow the attraction of the charged particles to the substrate. This is particularly useful in coating contours of conductive substrate. Such variations and alternate embodiments are contemplated, and can be made without departing from the spirit and scope of the invention.

It should further be noted that throughout the entire disclosure, the labels such as left, right, front, back, top, bottom, forward, reverse, clockwise, counter clockwise, up, down, or other similar terms such as upper, lower, aft, fore, vertical, horizontal, oblique, proximal, distal, parallel, perpendicular, transverse, longitudinal, etc. have been used for convenience purposes only and are not intended to imply any particular fixed direction or orientation. Instead, they are used to reflect relative locations and/or directions/orientations between various portions of an object.

In addition, reference to “first,” “second,” “third,” and etc. members throughout the disclosure (and in particular, claims) is not used to show a serial or numerical limitation but instead is used to distinguish or identify the various members of the group.

In addition, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of,” “act of,” “operation of,” or “operational act of” in the claims herein is not intended to invoke the provisions of 35 U.S.C. 112, Paragraph 6.

What is claimed is:

1. A method for coating a substrate, comprising:
providing a solvent;
dissolving desired solute within the solvent to form a solution;
diluting the solution to a composition capable of atomization;
cleaning the substrate;
heating the substrate;
atomizing the diluted solution into atomized vapor particles;
directing atomized vapor particles of the diluted solution towards the heated substrate to form a conformal layer of substantially dehydrated compound thereon; and
consolidating the substantially dehydrated compound into a coating of a nano-crystalline ceramic structure, with enhanced ceramic bonding with the substrate.

2. The method for coating a substrate as set forth in claim 1, wherein:
the solvent is substantially vaporized.

3. The method for coating a substrate as set forth in claim 1, wherein:
the solute is a resistive material.

4. The method for coating a substrate as set forth in claim 1, wherein:
the coating is transparent.

5. The method for coating a substrate as set forth in claim 1, further comprising:
cleaning the coated substrate to remove loose particulates.

6. A method for coating a substrate, comprising:
providing a combustible solvent;
dissolving desired solute within the solvent to form a solution;
diluting the solution to a composition capable of atomization;
atomizing the diluted solution into atomized vapor particles;
igniting the atomized vapor particles of the diluted solution to substantially to ignite and remove solvent, providing additional dehydration;
directing resulting atomized vapor particle solution with substantially removed solvent towards cleaned substrate to form a conformal layer of substantially dehydrated compound on the substrate;
consolidating the substantially dehydrated compound into a coating of a nano-crystalline ceramic structure, with enhanced ceramic bonding with the substrate.

7. The method for coating a substrate as set forth in claim 6, wherein:
the solvent is combustible.

8. The method for coating a substrate as set forth in claim 6, wherein:
the solvent is substantially vaporized.

9. The method for coating a substrate as set forth in claim 6, wherein:
the solute is a resistive material.

10. The method for coating a substrate as set forth in claim 6, wherein:
the coating is transparent.

11. The method for coating a substrate as set forth in claim 6, further comprising:
cleaning the coated substrate to remove loose particulates.

12. A coating, comprising:
an nano-crystalline structure comprised of resistive material.

13. The coating as set forth in claim 12, wherein:
the nano-crystalline structure of resistive material is generated by diluting a solution of the resistive material to a composition capable of atomization;
atomizing the diluted solution into an atomized vapor particles, directed towards a substrate to form a conformal layer of substantially dehydrated compound on the substrate;
heating the substantially dehydrated compound to form the coating of nano-crystalline structure of resistive material, with enhanced ceramic bonding with the substrate.

14. The coating as set forth in claim 13, wherein:
the atomized vapor particles are generated by an ultrasonic device.

15. An nano-crystalline structure, comprising:
an oxide compound with ceramic bonding structure.

16. The nano-crystalline structure as set forth in claim 15, wherein:
the oxide compound is generated by diluting a solution of the oxide compound to a composition capable of atomization;
atomizing the diluted solution into an atomized vapor particles, directed towards a substrate to form a conformal layer of substantially dehydrated compound on the substrate;
heating the substantially dehydrated compound to form a coating of nano-crystalline structure of the oxide, with enhanced ceramic bonding with the substrate.

17. The coating as set forth in claim 16, wherein:
the atomized vapor particles are generated by an ultrasonic device.
